(19) United States
(12) Patent Application Publication
(10) Pub. No.: US 2019/0267481 A1
(43) Pub. Date: Aug. 29, 2019

(54) Field-Effect Transistors (FETs)

(71) Applicant: Duet Microelectronics LLC, Raritan, NJ (US)

(72) Inventors: Ashok T. Ramu, Raritan, NJ (US); Robert Bayruns, Raritan, NJ (US)

(21) Appl. No.: 15/905,295

(22) Filed: Feb. 26, 2018

(51) Int. Cl. H01L 29/778; H01L 29/10; H01L 29/205; H01L 29/66

(52) U.S. Cl. CPC H01L 29/7785; H01L 29/1029; H01L 29/165; H01L 29/66462; H01L 29/205

(57) ABSTRACT

The present invention improves the linearity characteristics of a transistor, namely the input/output intercept points (IIP3/OIP3) and intermodulation distortion (IM3), while maintaining a high transconductance and high electron velocity in the conducting channel. The present invention also improves the manufacturability, yield, and immunity to bias-point drift, of a linear transistor. In one embodiment, the present invention implements triple pulse doping or even higher pulse doping for immunity to process variation as well as low parasitic leakage. In an alternative embodiment, the present invention implements a bilinear V-shaped composition grading for engineering the I_{D}-V_{GS} curve for high OIP3. In another alternative embodiment, the present invention implements a quadratic or U-shaped composition grading for engineering the I_{D}-V_{GS} curve for high OIP3.

### BACKGROUND OF THE INVENTION

### 1. Field of the Invention

The present invention relates to transistors, and in particular to field-effect transistors including a linear high-electron mobility transistor (HEMT).

### 2. Description of the Prior Art

Field-effect transistors (FETs), that exemplify solid-state electronic transistors in the present application, are three-terminal devices that operate based on the field effect. A voltage applied to a terminal called the “Gate Electrode” acts on mobile charge carriers remotely through an insulating/weakly conducting/semiconducting barrier. The mobile charge carriers are pulled into/depleted from a “channel” region, by means of electrostatic fields.

Depending on: (a) the voltage magnitude and voltage polarity applied externally to the gate electrode, (b) the polarity of charge being pulled into, or depleted from, the channel by the gate (negative for electrons, positive for electron vacancies also known as “holes”), and (c) the polarity and quantity of immobile fixed charges either present in the channel or in the barrier, the gate electrode may form or disrupt a conductive “bridge” in the channel region between two other terminals called the “Source Electrode” and the “Drain Electrode.”

For clarity of exposition, the convention used herein is that a positive voltage applied to the gate terminal attracts negatively charged electrons into an otherwise weakly conducting channel, thereby forming a conducting path that electrically bridges the electron-rich source and drain terminals. Application of a negative gate voltage would then disrupt the conducting path, thus electrically isolating the source and drain terminals. This is called a depletion-mode transistor. High-electron mobility transistors (HEMTs) are known in the prior art in which the barrier is a semiconductor as well, usually an alloy different in elemental composition from the channel material. With a semiconductor barrier, it is generally easier in practice to insert fixed electrical charges that would further modulate the response of electrons in the channel to the gate voltage. In the majority of the prior art, HEMTs entail confinement of electrons to high-purity channels devoid of intentionally introduced impurities called “dopants” present in the channels of most other flavors of FETs, thereby realizing high electron mobility.

The operation of the FET is best visualized by means of a partial “band energy diagram,” which is the energy of the edge of the conduction band (CB) pictured as a function of spatial position. The diagrams are constructed such that under the prevalent electrostatic fields, electrons tend to pool near the bottom of the profile. The dashed lines show the “chemical potential,” also known as Fermi level, which may for our present purposes be considered an energy reference for the CB. It is important to note that lower the CB energy with respect to this reference at any point, larger the electron concentration at that point.

FIG. 1A-1E illustrate a FET and its characteristics in the prior art. As shown in FIG. 1A, the FET 10 has a source 12, a gate 14, a drain 16, a conducting cap 18, a front barrier 20, a pulse-doping layer 22 incorporated within front barrier 20, a channel 24, and a back barrier 26 formed on a substrate 28. FIG. 1D shows the band energy diagram in a vertical section through the center of FIG. 1A, cutting through the gate metal, front barrier, channel, back barrier and substrate. The barrier 26 is made of an oxide, or a semiconductor of a different material or alloy composition than the channel. An example plot of material elemental composition vs vertical location is illustrated in FIG. 1E. In FIG. 1D, with such a material stack, a conduction band “well” forms at the barrier-channel interface, where electrons can be made to pool by increasing the gate voltage, as explained below. This pool of electrons once created by turning on the gate voltage, would bridge the source and drain terminals and allow an electrical current.

FIG. 1B shows schematically the CB energy as a function of position in the channel, across the device of FIG. 1A horizontally sectioned through the dash-dotted line shown in FIG. 1A, from source to drain terminals, with the dots representing electrons, and the dashed line representing a reference energy (the so-called chemical potential or Fermi level) vs. position. If the gate voltage is highly negative, the CB energy in the channel under the gate electrode is high, presenting a barrier that blocks electrons from transferring from source to drain, even if the drain CB energy is lower than that of the source. As the gate voltage increases, the barrier decreases, until a threshold gate voltage is reached, as shown in FIG. 1C, which represents a conduction band profile horizontally across the device of FIG. 1A sectioned through the dash-dotted line shown in FIG. 1A, with the dots representing electrons, and the dashed line representing the Fermi level vs. position. At this threshold, electrons in the source can gain enough energy from random thermal excitations to overcome the barrier, after which they are accelerated by the drain voltage into the drain terminal, providing current at the drain terminal.

FIG. 2A plots the drain current (I_{D}) versus the gate-to-source voltage (V_{GS}). The source is chosen to be the zero of potential throughout this document. A fixed positive voltage is applied to the drain to collect the electrons launched from the source. This drain voltage is often close to the highest DC voltage in the chip or system, namely the positive power supply rail. As described in the previous section, a threshold voltage is present until which the drain current is small, followed by an abrupt increase as the barrier becomes low enough to be surmounted by electrons thermally excited from the source. Beyond this point, the current at the drain monotonically increases as the increasing gate voltage attracts more and more electrons into the channel.

FIG. 2B shows plots of gₘ₁ and gₘ₃, the first and third partial derivatives respectively of the drain current with respect to the gate voltage illustrated in FIG. 2A. By definition:

$$\begin{matrix}{g}_{m 1} = \frac{\partial {I}_{D}}{\partial {V}_{GS}} & ( 1 ) \\ {g}_{m 3} = \frac{1}{6} \frac{{\partial }^{3} {I}_{D}}{\partial {V}_{GS}^{3}} & ( 2 )\end{matrix}$$

and, for the sake of completeness, the second derivative gₘ₂ is defined as:

$${g}_{m 2} = \frac{1}{2} \frac{{\partial }^{2} {I}_{D}}{\partial {V}_{GS}^{2}} \qquad ( 3 )$$

It is to be noted carefully that throughout this document, as per standard convention in the field, whenever the symbol gₘ occurs without a number in the subscript, it is understood to refer to gₘ₁.

Given a certain quiescent direct-current (DC) gate voltage V_{GS0}, at which the current is I_{D0}, for small voltage and current excursions around V_{GS0} and I_{D0}, the Taylor theorem gives:

i_{D}=gₘ₁v_{gs}+gₘ₂v_{gs}²+gₘ₃v_{gs}³+ . . . . (4)

where i_{D}=(I_{D}−I_{D0}) and v_{gs}=(V_{Gs}− V_{GS0}) are respectively the current and voltage excursions about the quiescent point.

As shown in Equation 4 above, the first two terms after the linear term gₘ₁v_{gs} result in distortion of the output signal from the ideal situation where the transistor simply amplifies the input signal by a constant factor. Especially significant for communication systems is the gₘ₃ distortion term, which mixes input signals from two or more frequency channels adjacent to the channel of interest and places the output back in that channel, making it very difficult to filter out the information leaking from the adjacent channels.

Again, with reference to Equation 4 above, an important metric of the distortion due to the gₘ₃ term is called “output intercept point” or OIP3, which is defined as follows: consider a transistor fed by a pure sinusoidal input at a single (“fundamental”) frequency=f, with input power chosen such that the power in the fundamental frequency at the output equals the power in the third harmonic (3f) at the output. Each of these powers expressed in deciBels (dB) equals OIP3.

OIP3 depends on gₘ₁, on gₘ₃, and on the load resistance R_{L}. It can be shown from the definition that, in units of deciBel-milliwatts (dBm), OIP3 is given by the equation:

$$OIP 3 = 20 {log}_{10} ( \sqrt{\frac{4 {g}_{m 1}}{3 {g}_{m 3}}} ) + 20 {log}_{10} ( {g}_{m 1} {R}_{L} ) \qquad ( 5 )$$

The above Equations 1-5 are the basic equations used to describe the optimization and figures of the merits for prior art FET designs and for the inventions presented in this application. Conventionally, I_{D}, gₘ₁, gₘ₂, gₘ₃ and OIP3 are all reported per mm device width.

FIG. 2C shows OIP3 vs VGS for the exemplary FET of FIGS. 1D and 1E in the prior art. A value of 40 dBm to 50 dBm is considered exceptional for a 1 mm wide FET. The width is the dimension perpendicular to the plane of FIG. 1A. Aside from an unusable peak at extremely low currents close to the FET threshold, OIP3 remains well below 40 dBm. Although OIP3 increases with gate voltage, and furthermore, although some approaches focus on the constant-gₘ₁ regime as mentioned later, very high gate quiescent voltages and drain currents may not be suitable for operating the FET at for three reasons: (a) low power efficiency, (b) the possibility of the barrier under the gate beginning to conduct, increasing the noise and eventually collapsing the drain current, and (c) overheating of the FET due to high quiescent power dissipation

Finally, as gₘ₃ tends to zero, OIP3 increases without bound. In practice, there will still be third harmonic content in the FET power output, and hence finite OIP3 due to the omitted terms in the Taylor theorem of powers of v_{gs} of 5 or higher. However, these are likely to be rather weak for modest gate voltage excursions v_{gs}, meaning that the OIP3 peaks will still be pronounced.

The bulk of the prior art related to HEMTs emphasizes approaches to increase the speed of operation as characterized by either f_{T} or fₘₐₓ, the frequencies of current-gain cutoff and maximum power gain cutoff, respectively, such as described in Ross, Svensson, and Lugli, “Pseudomorphic HEMT Technology and Applications.”

The exemplary FET in the prior art, shown in FIGS. 1A-1E, features a delta-doped (also called pulse-doped) layer in the front barrier, directly beneath the gate. This is an extremely thin layer (typically a few nanometers wide) of impurities incorporated intentionally into the semiconductor, either in-situ during material growth, or by implanting impurity ions into the material after growth. These impurities become electrically charged, with positive polarity in the barrier resulting in negative electrons imaged in the channel. so that the threshold gate voltage may be adjusted. In the absence of this extra supply of electrons, the gate voltage may need to be too high for sufficient numbers of electrons to pool in the channel and conduction to begin.

FIG. 3 shows an embodiment of the HEMT of the prior art with a second delta-doped (or pulse-doped) layer incorporated in the back-barrier layer underneath the channel. As shown in FIG. 3, the HEMT 30 has a source 32, a gate 34, a drain 36, a conducting cap 38, a front barrier 40, a first delta-doping layer 42 incorporated within the front barrier 40, a channel 44, and a back barrier 46 formed on a substrate 48. The second delta-doped layer 50 is incorporated within the back barrier 46. Although it is most often used to further control the threshold voltage of the HEMT, this second delta has been stated to improve device linearity, such as described in Kalna et al., “Role of Multiple Delta Doping in PHEMTs Scaled to Sub-100 nm Dimensions,” SOLID-STATE ELECTRONICS Vol. 48 (2004), pp. 1223-1232; and Chiu et al., “Microwave Performance of Double Delta-Doped High Electron Mobility Transistor With Various Lower/Upper Planar-Doped Ratio Designs,” IEEE TRANSACTIONS ON ELECTRONIC DEVICES, Vol. 55, No. 1, January 2008, pp. 256-260.

FIG. 5A shows an embodiment in the published prior art of the schematic FIG. 3. FIGS. 5B-5C show an embodiment of an HEMT in the prior art where the channel or the front barrier are uniformly doped with impurities, such as described in Lin et al., “A Delta-Doped InGaP/InGaAs PHEMT with Different Doping Profiles for Device-Linearity Improvement,” IEEE TRANSACTIONS ON ELECTRON DEVICES, August 2007, pp. 1617-1625. Intentionally introducing dopants in the channel drastically reduces the mobility, defeating the purpose of a high-electron-mobility transistor. Doping the front barrier uniformly (in place of a sharp delta or pulse located away from the channel interface) results in scattering of electrons in the channel by remote Coulombic forces, thereby also reducing the electron mobility, and hence reducing the speed. Furthermore, a uniformly doped barrier is typically avoided in HEMTs in favor of a delta-doped layer, due to concerns of a current leakage path forming in the barrier, bridging source and drain even when the HEMT is supposedly off, as described in Mishra and Singh, “Semiconductor Device Physics and Design”.

FIGS. 4A-4B shows an embodiment in the prior art where the channel is heavily doped in an initial buffer layer close to its interface with the barrier, such as described in Inoue et al., “Linearity Improvement of GaN HEMT for Wireless Communication Applications,” SEI TECHNICAL REVIEW, No. 78, April 2014, pg. 48-52. Once again linearity is improved as in Lin et al., but at the cost of poor electron mobility in the HEMT. Furthermore, a heavily doped layer in the channel makes it difficult for the device to be turned off by the gate, and if the threshold voltage falls below the negative supply rail, the device cannot be turned off at all.

Park et al., “Electron Gas Dimensionality Engineering in AlGaN/GaN High Electron Mobility Transistors Using Polarization,” APPLIED PHYSICS LETTERS, Vol. 100 (2012), pp. 063507-1 to 063507-3; discusses composition grading of AlGaN/GaN HEMT channels in the prior art for linearity improvement. Unusual physics is seen in these nitride semiconductors including (a) strong molecular polarization and (b) crystal structures lacking reflection symmetry along major crystallographic directions. These two characteristics together open up the possibility of inducing a large number of carriers in the channel by linearly varying (“grading”) the alloy composition, offering a very powerful technique for tuning a device's electrical characteristics. This tuning technique is not available on most technologically important platforms, such as exemplified in the inventive devices, which are either non-polar or weakly polar.

Grading has been mentioned in the context of Metal-Semiconductor FETS (MESFETs), such as described in Sechi and Bujatti, “Solid-State Microwave High-Power Amplifiers”. It is worthwhile noting here that: the word “grading” as used by the authors of refers to gradation of the impurity doping profile, instead of alloy composition, as in the present application. In addition, the stated purpose of this “grading” in authors has been to achieve “constant gₘ.” As shown in FIGS. 2A-2C, gₘ always becomes constant at high enough V_{GS} (and hence bias current), resulting in steadily but gradually increasing OIP3. However, operating the HEMT at such high currents is undesirable because of noise degradation due to gate conduction, due to low power efficiency, and due to difficulties sinking the extra heat to keep the device at operational temperatures. It is noted that, as illustrated in FIGS. 7A-B, 8C and 9C, the inventive devices are operated at lower currents and V_{GS}, where gₘ₁ is far from constant, instead varying close to linearly, with varying V_{GS}.

Finally, it is noted that doped and alloyed semiconductors are structurally and functionally different. Doping involves introducing impurities that ionize by either losing or gaining one or more electrons. Typically doping involves introducing no more than one impurity atom per 10⁴ (that is, 10,000) host atoms. On the other hand, alloying involves replacing a host atom with another of the same valence (e.g. gallium with indium) so that there is no charge imbalance to the first order. Typically alloying involves replacing 1% to 50% of atoms of the semiconductor with another of equal valence.

### OBJECTS AND SUMMARY OF THE INVENTION

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented later.

The present invention improves the linearity characteristics of a transistor, namely the input/output intercept points (IIP3/OIP3) and intermodulation distortion (IM3), while maintaining a high transconductance (gₘ) and high electron velocity (vₛₐₜ) in the conducting channel. The present invention also improves the manufacturability, yield, and immunity to bias-point drift, of a linear transistor.

In one embodiment, the present invention implements a bilinear V-shaped composition grading for engineering the I_{D}-V_{GS} curve for high OIP3. In an alternative embodiment, the present invention implements a quadratic U-shaped composition grading for engineering the I_{D}-V_{GS} curve for high OIP3. In another alternative embodiment, the present invention implements triple pulse doping or even higher pulse doping for immunity to process variation as well as low parasitic leakage.

The present invention with graded channels has a broader OIP3 peak than uniform channels of the prior art, for larger signal operation. The present invention with graded channels has broader OIP3 peak than uniform channels of the prior art, for more room for process variation, bias-point drift and temperature drift. The present invention has less variation of OIP3 with doping, hence higher yield, in triple-pulse doping over 2-pulse doping. The present invention has reduced leakage through the barrier with two pulses in a barrier, unlike a uniformly doped barrier. The present invention has U and V grading schemes which work even with non-polar III-Vs and even with SiGe, unlike linearly graded polar AlGaN as in the prior art. The present invention has high electron mobility preserved by grading without doping, unlike heavily doped GaN spacer or uniformly doped channel as in the prior art.

### BRIEF DESCRIPTION OF THE DRAWINGS

The foregoing summary, as well as the following detailed description of presently preferred embodiments of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1A is a cross-sectional view of a field-effect transistor implementing an HEMT in the prior art;

FIG. 1B is a conduction band profile taken horizontally across the device in FIG. 1A for a low gate voltage;

FIG. 1C is a conduction band profile taken horizontally across the device in FIG. 1A for a high gate voltage;

FIG. 1D is a conduction band profile taken vertically through the center of the device in FIG. 1A;

FIG. 1E is a material composition profile taken vertically through the center of the device in FIG. 1A;

FIG. 2A is a graph of I_{D} vs. V_{GS} of the device in FIG. 1A;

FIG. 2B is a graph of gₘ₁ and gₘ₃ vs. V_{GS} of the device in FIG. 1A;

FIG. 2C is a graph of OIP3 vs. V_{GS} of the device in FIG. 1A;

FIG. 3 is a FET with back barrier pulse doping in the prior art;

FIG. 4A is a FET with a heavily doped spacer in the prior art;

FIG. 4B is a conduction band energy diagram of the FET in FIG. 4A;

FIG. 5A is FET having a double-delta doped structure in the prior art;

FIG. 5B is a FET having a uniformly doped channel in the prior art;

FIG. 5C is a FET having a uniformly doped barrier in the prior art;

FIG. 6 is a FET having a triple-pulse doped structure of the present invention;

FIG. 7A is a graph of I_{D} vs. V_{GS} for the FET in FIG. 6;

FIG. 7B is a graph of gₘ₁ and gₘ₃ vs. V_{GS} for the FET in FIG. 6;

FIG. 7C is a graph of OIP3 vs. V_{GS} for the FET in FIG. 6;

FIG. 7D is a material composition profile for the FET in FIG. 6;

FIG. 7E is a CB energy profile for the FET in FIG. 6;

FIG. 8A is a material composition profile for an inventive V-graded structure;

FIG. 8B is a CB energy profile for the inventive V-graded structure of FIG. 8A;

FIG. 8C is a graph of I_{D} vs. V_{GS} for the inventive V-graded structure of FIG. 8A;

FIG. 8D is a graph of OIP3 vs. V_{GS} for the inventive V-graded structure of FIG. 8A;

FIG. 9A is a material composition profile for an inventive U-graded structure;

FIG. 9B is a CB energy profile for the inventive U-graded structure of FIG. 9A;

FIG. 9C is a graph of I_{D} vs. V_{GS} for the inventive U-graded structure of FIG. 9A; and

FIG. 9D is a graph of OIP3 vs. V_{GS} for the inventive U-graded structure of FIG. 9A.

To facilitate an understanding of the invention, identical reference numerals have been used, when appropriate, to designate the same or similar elements that are common to the figures. Further, unless stated otherwise, the features shown in the figures are not drawn to scale, but are shown for illustrative purposes only.

### DETAILED DESCRIPTION OF THE PREFERRED EMBODIMENTS

Certain terminology is used in the following description for convenience only and is not limiting. The article “a” is intended to include one or more items, and where only one item is intended the term “one” or similar language is used. Additionally, to assist in the description of the present invention, words such as top, bottom, upper, lower, front, rear, inner, outer, right and left may be used to describe the accompanying figures. The terminology includes the words above specifically mentioned, derivatives thereof, and words of similar import.

The present application focuses on compound/alloy semiconductors (e.g. group-III arsenides/phosphides, silicon-germanium etc.) that do not exhibit any/significant polarization-induced charge upon grading the elemental composition. In such semiconductors, the simple artifice of linearly grading the composition over the channel depth, as done in the prior art such as in Park et al., does not affect linearity.

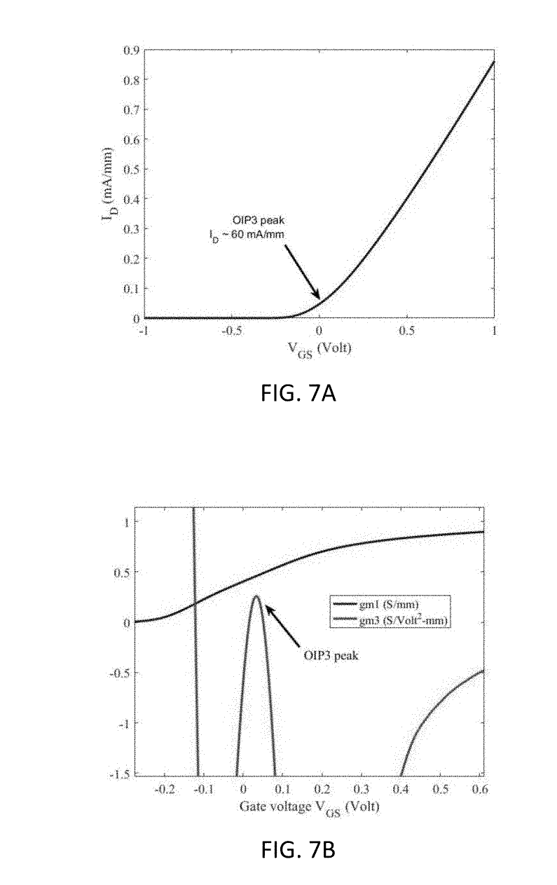

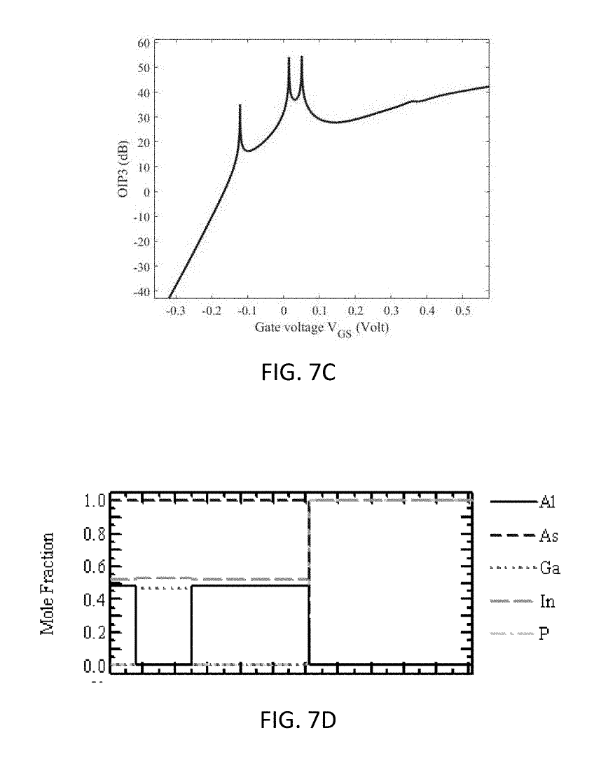

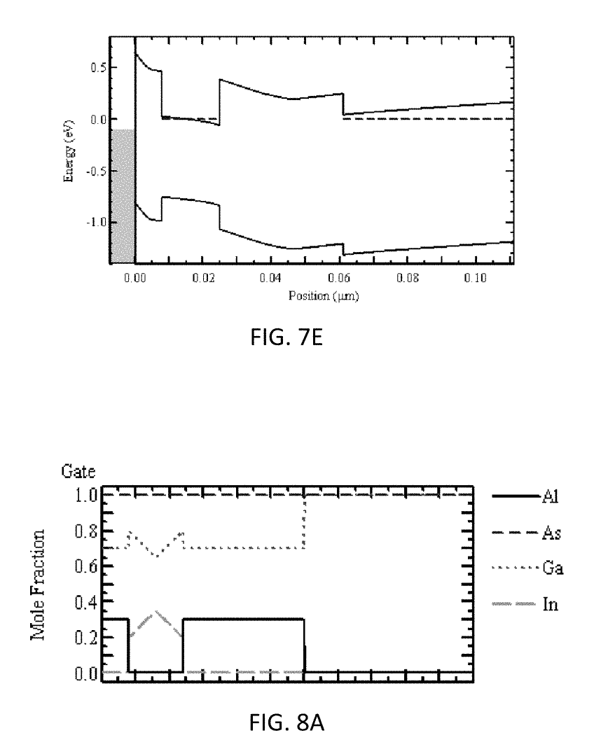

The present application also focuses on bias points much closer to the threshold voltage, as shown in FIG. 7A-B where gₘ₁ is not necessarily constant, but where gₘ₃ is low so that OIP3 increases above 35 dBm. As mentioned herein, biasing where gₘ is constant results in noise, power efficiency and thermal issues. Large peaks in OIP3 can be expected if the FET is designed for gₘ₁ linear with V_{GS} and (hence) zero gₘ₃, even if gₘ₁ is not constant or especially large, and this will be a strategy for improving OIP3.

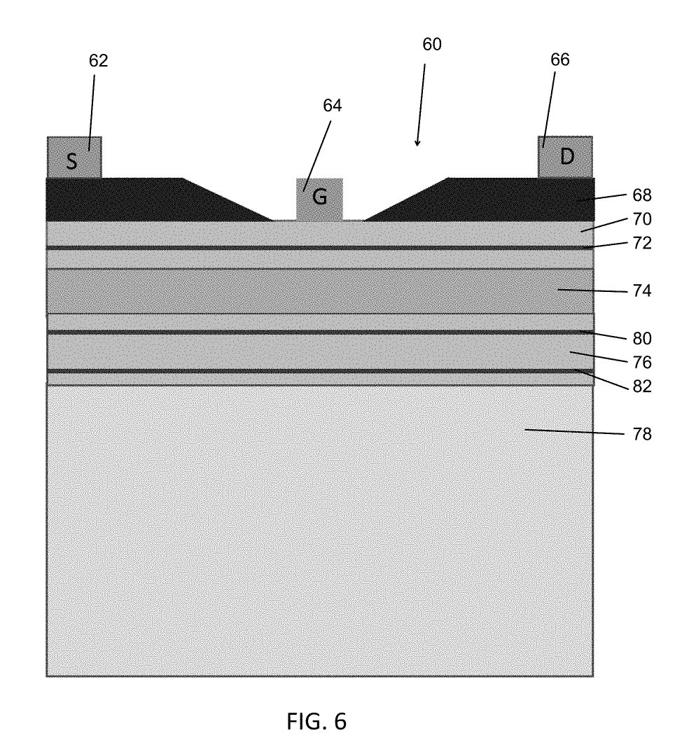

In a first embodiment, the present invention implements triple-pulse doping for increased yield of linear HEMTs. FIG. 6 shows the inventive structure with three delta-doped (pulse doped) layers, two in the back-barrier and one in the front. As shown in FIG. 6, the HEMT 60 has a source 62, a gate 64, a drain 66, conducting caps 68, a front barrier 70, a first pulse-doping layer 72, a channel 74, and a back barrier 76 formed on a substrate 78. The substrate may optionally include growth buffers for clean, dislocation-free growth. Two delta-doped layers 80, 82 are incorporated within the back barrier 76.

The concentration of intentional impurities (dopants) in the three pulses can be chosen so as to give a pronounced peak in OIP3 vs V_{GS}. FIG. 7A and FIG. 7B show an I_{D} vs V_{GS} profile and an OIP3 peak for an instance of the inventive structure. The OIP3 peak, although tall, is rather narrow; for example, the width over which OIP3>40 dBm is about 50 millivolts.

The triple-pulse doping of the present invention may be implemented either by metalorganic chemical vapor deposition (MOCVD), or by molecular beam epitaxy (MBE). Any growth technique capable of achieving monatomic resolution will work, with MOCVD and MBE providing high resolution.

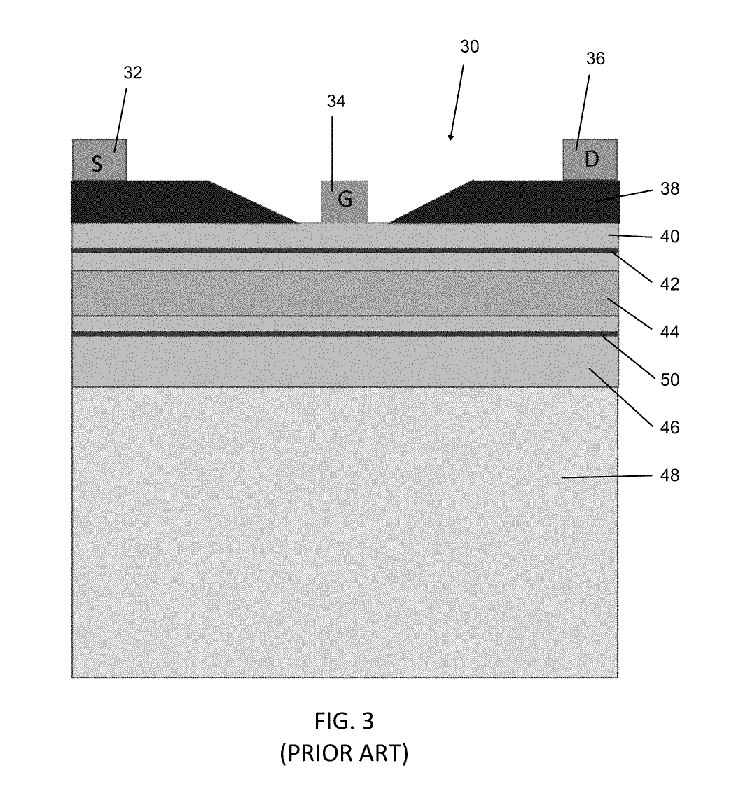

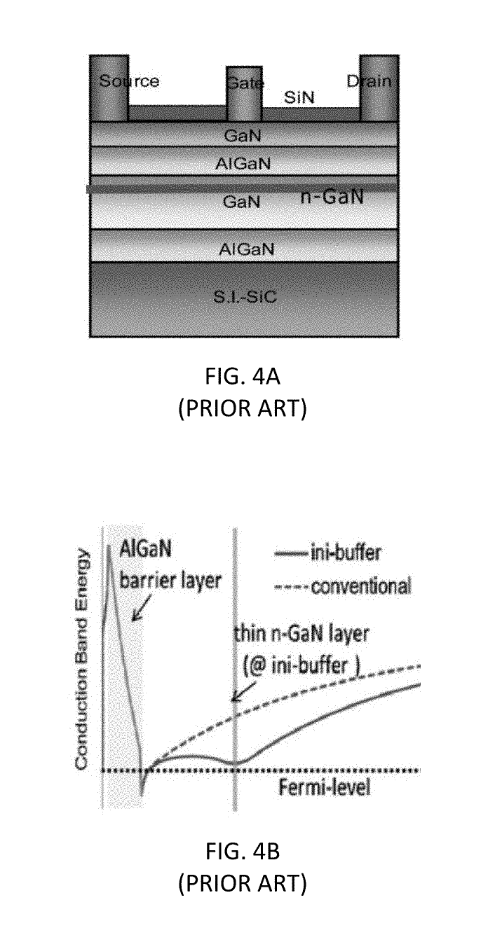

Ideally, the characteristics of the triple-pulse-doped structure could theoretically be exactly replicated with the prior art double-pulse doped structure of FIG. 3, with one pulse in each barrier, and with distance from the channel and impurity concentration chosen appropriately. In reality, however, fabrication methods cannot manufacture large numbers of HEMTs all having precisely the same areal concentration of impurities. Manufacturing process variation on the areal delta-doping concentration δ can be modelled as a Gaussian distribution with standard deviation a fixed factor f (e.g. f=10%) times the expected (nominal, average, mean) value [symbol] δ [symbol] :

\sqrt{ [symbol]δ² [symbol]}=f [symbol] δ [symbol] (6)

The inventive triple-pulse doped structure of the present invention provides immunity against statistical fluctuations in impurity concentrations, resulting in higher manufacturing yield, as demonstrated herein. For many material growth techniques, such as MOCVD, f=0.2 is a typical stringent specification, meaning the statistical variation is +/−10% of the average concentration.

It can be shown by the Poisson's equation of electrostatics that the FET electrical characteristics depend, not on the detailed distribution of impurities in the back-barrier, but instead on a lumped quantity: the so-called dipole moment P of the distribution

P=∫₀^{d}^{_{B}}dx′(d_{B}−x′)N(x′) (7)

Here, N(x) is the volume concentration of charged impurities at a distance x from the channel-to-back-barrier interface, and d_{B} is the back-barrier thickness. For two Gaussian pulses in the back barrier of net areal concentration δ₁ and δ₂, with respective peaks at a distance d₁ and d₂ from the interface:

P=(d_{B}−d₁)δ₁+(d_{B}−d₂)δ₂ (8)

Assuming the statistics of δ₁ and δ₂ are described by Gaussian distributions, assuming equal factors f=\sqrt{ [symbol]δ² [symbol]}/ [symbol] δ [symbol] for each, it is well known that the standard deviation in the dipole moment P is given by:

$$\sqrt{〈 {P}^{2} 〉} = f \sqrt{{( {d}_{B} - {d}_{1} )}^{2} {δ}_{1}^{2} + {( {d}_{B} - {d}_{2} )}^{2} {δ}_{2}^{2} + 2 {δ}_{1} {δ}_{2} ( {d}_{B} - {d}_{1} ) ( {d}_{B} - {d}_{2} ) {ρ}_{12}} \qquad ( 9 )$$

where ρ₁₂ is the correlation coefficient between the two delta-doping concentrations, with −1≤ρ₁₂≤+1. The lower the correlation coefficient, the lower the standard deviation in the dipole moment. It may be shown that:

$$\sqrt{{( {d}_{B} - {d}_{1} )}^{2} {δ}_{1}^{2} + {( {d}_{B} - {d}_{2} )}^{2} {δ}_{2}^{2} + 2 {δ}_{1} {δ}_{2} ( {d}_{B} - {d}_{1} ) ( {d}_{B} - {d}_{2} ) {ρ}_{12}} \leq 〈 P 〉 \qquad ( 10 )$$

This yields the central result for the triple delta doped structure of the present invention:

\sqrt{ [symbol]P² [symbol]}≤f [symbol] P [symbol] (11)

For a double-pulse-doped HEMT, with single doping layer in the back-barrier, the standard deviation \sqrt{ [symbol]P² [symbol]} is by definition exactly the factor f times the mean value <P>. Thus, for the same nominal value of the dipole moment P, and hence the same nominal electrical characteristics, the triple-pulse doped structure always shows less statistical variation, and therefore higher manufacturing yield, than the two-pulse doped structure.

By modeling or measuring the statistical correlation between the concentration of the pulses, the standard deviation \sqrt{ [symbol]P² [symbol]} can be minimized, either numerically or analytically using, [symbol] for example, the method of the Lagrange multiplier. This would help to design the triple-pulse doped structure with design variables δ₁, δ₂, d₁ and d₂, that for given nominal electrical characteristics, represented by a fixed (P), has the highest yield mathematically possible.

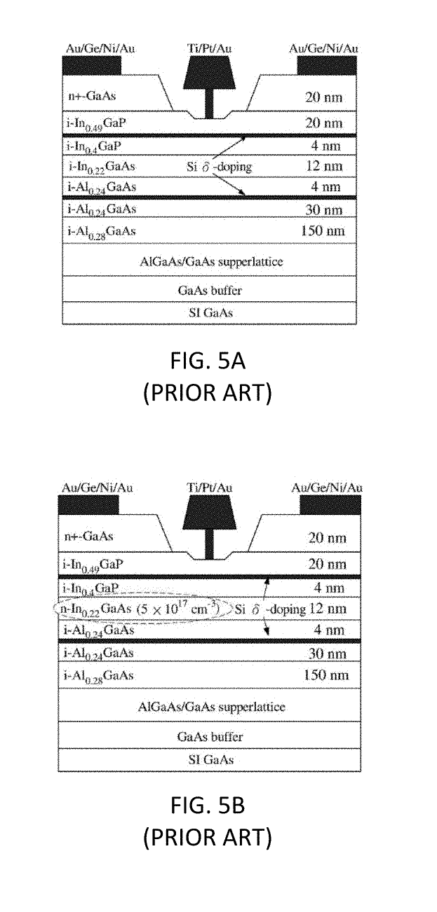

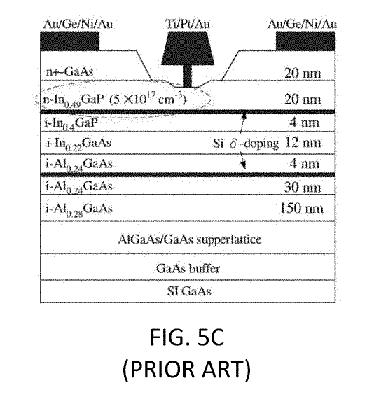

An important feature of the triple delta doped barrier is that high linearity devices may be achieved with high manufacturing yield without the risk of current leakage through the back barrier. This risk is carried by uniformly doped barriers (front or back) as in the prior art, such as shown in FIG. 5C, where the uniform doping is in the front-barrier. By contrast, in the inventive triple-pulse doped device of the present invention, the two pulses can be placed far enough apart from each other that their profiles do not overlap, thus eliminating leakage paths from forming between the pulses.

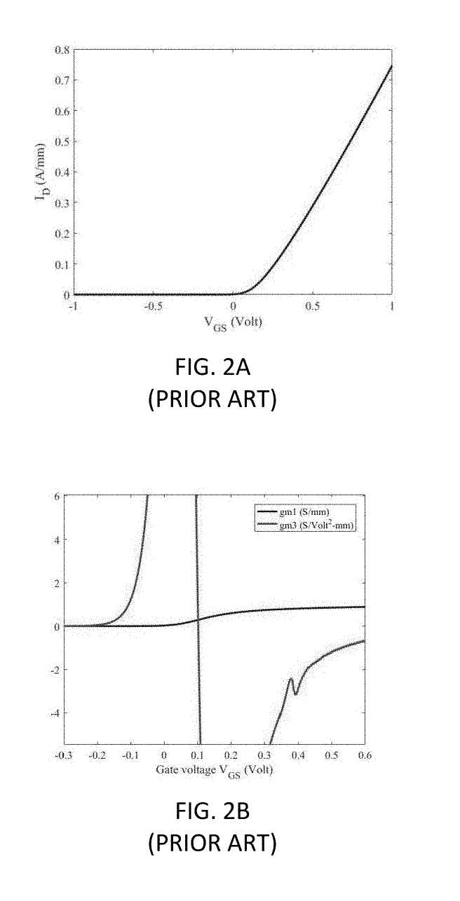

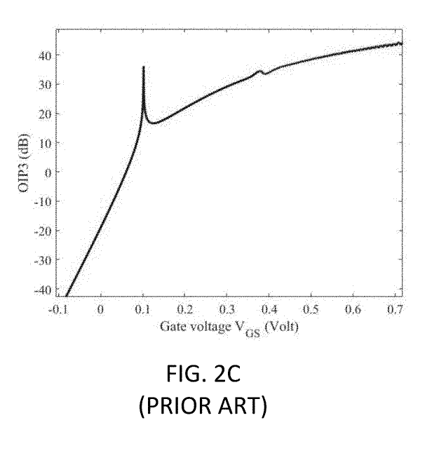

In an alternative embodiment, the present invention includes an alloy-composition graded channel for FET devices with broad and tall OIP3 peaks. Upon examination of the respective gₘ₃ and OIP3 profiles shown in the present invention in FIGS. 7B and 7C, as well as for prior art structures such as shown in FIG. 2B-2C, it is observed that the triple-pulse doped structure exhibits a zero-crossing of gₘ₃, while the prior-art HEMT has no zero-crossings apart from at the threshold gate voltage. It is this zero-crossing that results in high OIP3 for the triple-pulse device, according to the basic equations disclosed herein. Alloy composition-graded channels may be used to even further refine the position and enlarge the width of the OIP3 peaks through engineering of these zero-crossings, as described later.

The alloy-compositional grading may be implemented either by MOCVD or by Molecular Beam Epitaxy (MBE). Any growth technique capable of achieving monatomic resolution will work, with MOCVD and MBE providing high resolution.

In order to grade the alloy composition during MOCVD growth, the flow rates of the source gases, such as trimethyl indium or TMI, are varied with time by computerized control of the mass-flow controller valves. The computer varies the gas flow rates according to a previously established calibration curve for composition vs. flow rate.

Alternatively, during MBE growth, sources containing constituent elements, such as indium, gallium, etc., are contained in separate cells that are heated to the boiling point of the respective source. The alloy composition is varied during growth by computerized control of the heater temperature, and hence the vapor pressure, of each source according to a previously established calibration curve for alloy composition vs temperature. Another method available to the computer controlling the growth is to open and close a shutter in front of each source leading to the growth chamber. A sequence of steps for opening and closing the source shutters maybe programmed into the controller, in a manner known in the art, for precise monatomic layer control over the alloy composition.

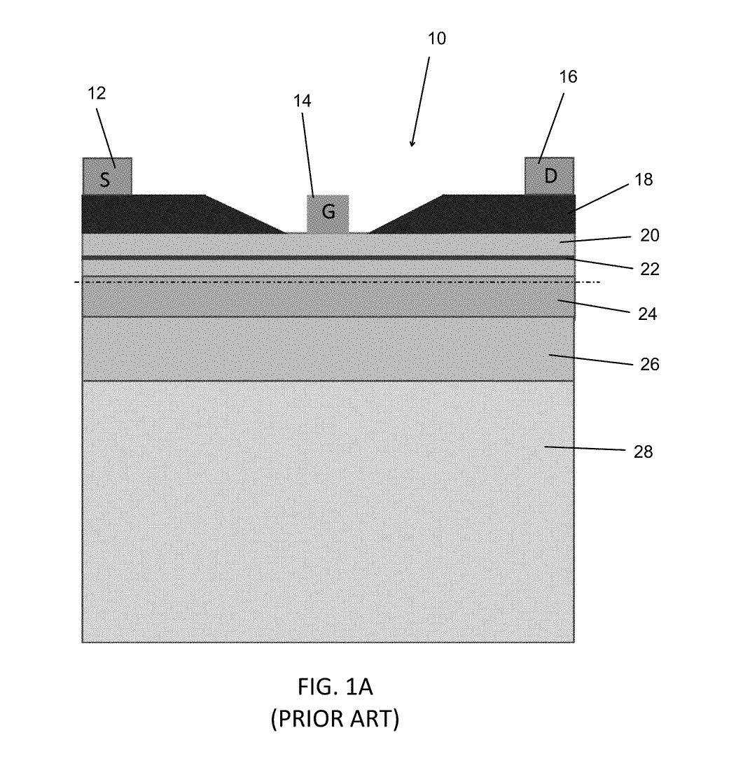

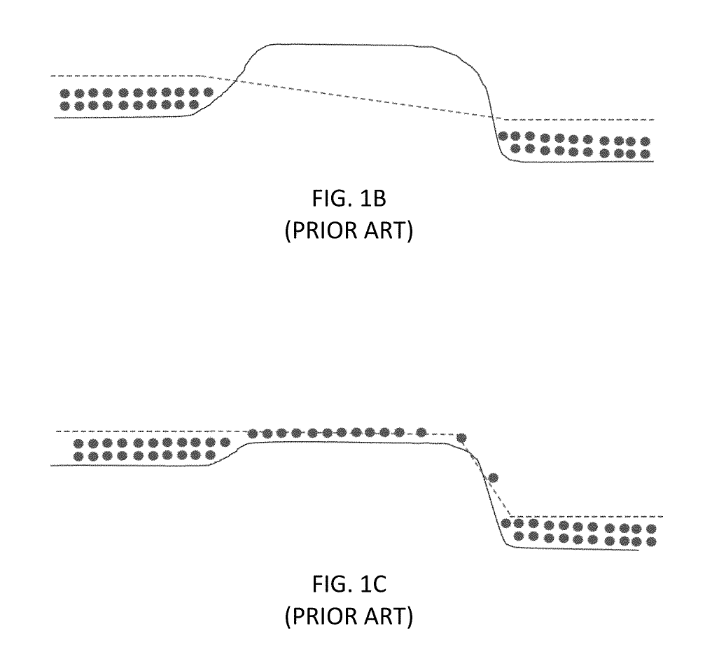

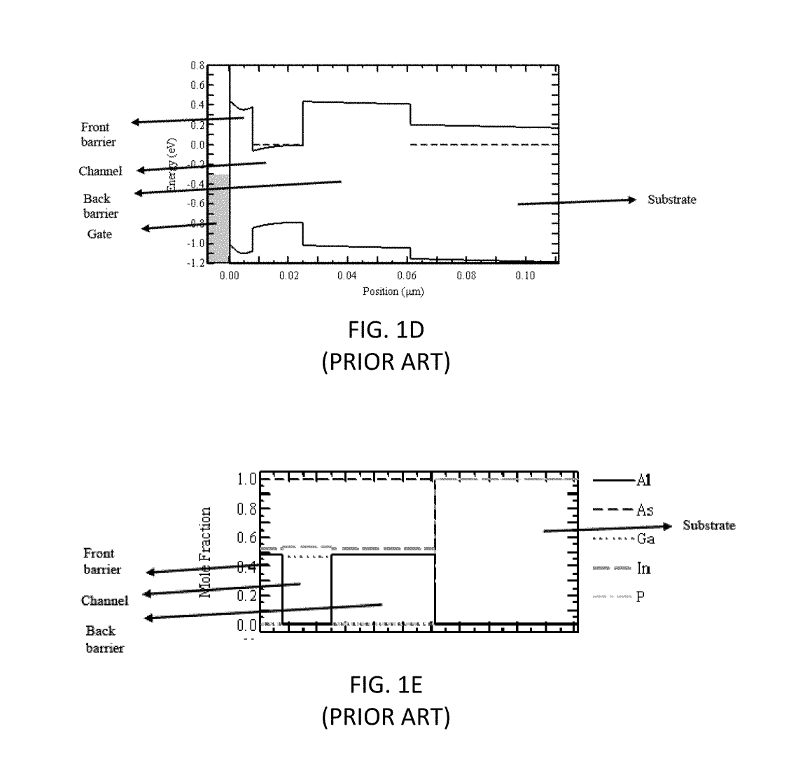

Conduction band profiles for the prior art in FIG. 1D, and the triple-pulse doped HEMT of the present invention in FIG. 7E, respectively, show the point in the channel where the CB edge energy is closest to the chemical potential reference. As discussed earlier, this is the point where electrons tend to pool and are at their highest concentration. When conduction begins, the prior art devices described in FIG. 1A have the highest electron concentration near the front of the channel, while the triple-pulse doped device of the present invention, or the nominally equivalent double-doped device of the prior art of FIG. 3, shows peak electron concentration towards the back of the channel.

By spreading out the onset of conduction amongst various points in the channel, rather than restricting conduction to the front of the channel, the device linearity improves. In the inventive device described herein, this insight for improving linearity is used to sculpt the I_{D}-V_{GS} curve in such a manner as to exhibit the desired derivatives gₘ₁ and gₘ₃.

One way to alter the depth profile of electron concentration in the channel is by altering the elemental composition profile either gradually, such as by alloy-compositional grading, or abruptly such as by forming heterojunctions. The following inventive non-uniform-alloy-compositional structures increase the width of the OIP3 peak, thus rendering the HEMT linear over a larger input voltage swing.

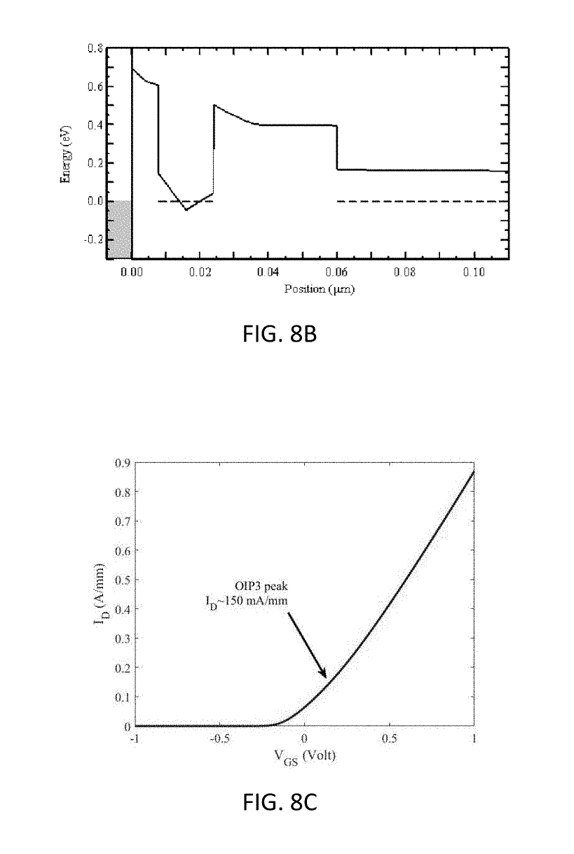

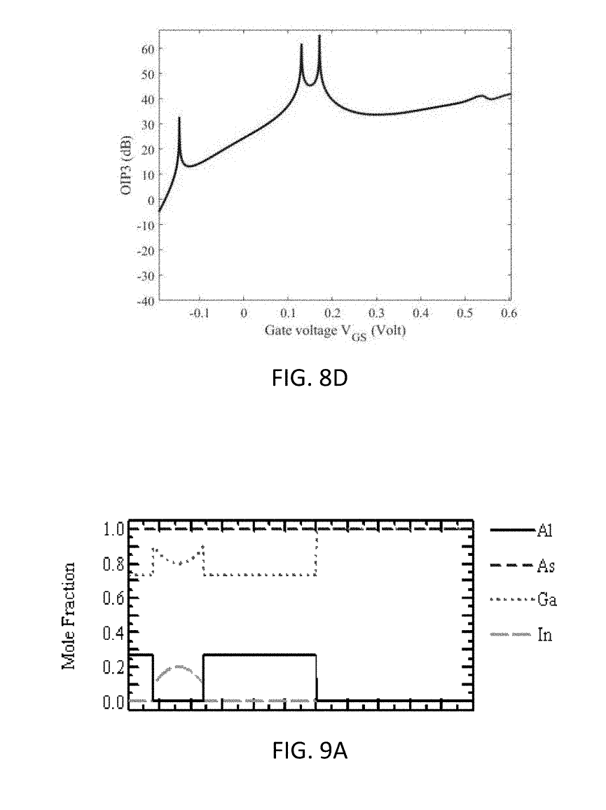

In one embodiment, a bi-linear V-graded channel is formed, as shown in FIGS. 8A-8B, which illustrate the composition vs. depth and CB energy profile vs, depth, respectively, of an exemplary inventive device, an Al_{0.3}Ga_{0.7}As barrier/InGaAs channel/Al_{0.3}Ga_{0.7}As back-barrier/GaAs substrate HEMT. The indium content of the InGaAs channel is alloy-compositionally graded linearly up from about 20% to about 35% indium over the first half of the channel, and then down from about 35% back to about 20% indium over the second half.

As shown in FIG. 8B, a notch in the conduction band profile is formed near the center of the channel. Here the band energy is minimum, and electrons tend to accumulate here at the onset of a threshold gate voltage. As the gate voltage increases, the back of the channel also begins contributing to the drain current, followed eventually by a rapid and uniform increase of current as the front of the channel becomes involved. FIGS. 8C-8D show that, by thus spreading the onset of conduction, the OIP3 peak broadens considerably, so that the width over which OIP3 is >40 dBm is now about 85 millivolts.

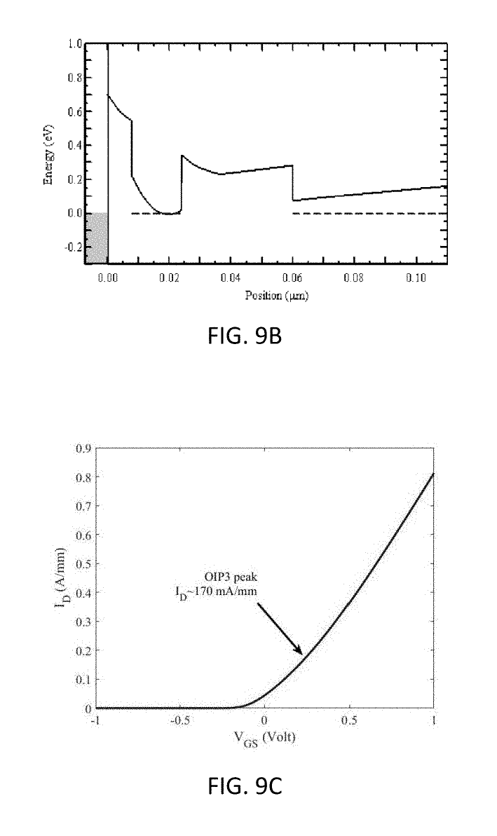

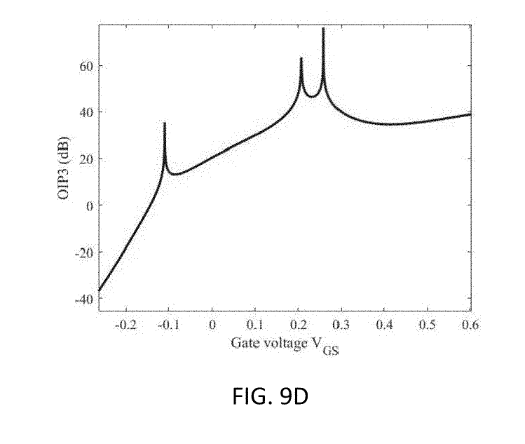

In an alternative embodiment, a bi-quadratic U-graded channel is formed. FIGS. 9A-9B show the composition and CB energy profile vs position, that is, depth, of an exemplary inventive device, an Al_{0.27}Ga_{0.73}As barrier/InGaAs channel/Al_{0.27}Ga_{0.73}As back-barrier/GaAs substrate HEMT. The indium content of the InGaAs channel is alloy-compositionally graded quadratically, to form a parabolic or U-shape, as a function of position up from about 10% to about 20% indium over the first half of the channel, and then quadratically down from about 20% back to about 10% indium over the second half.

A minimum in CB energy is formed within the channel, as illustrated in FIG. 9B, where electrons tend to accumulate at the onset of a threshold gate voltage. As the gate voltage increases, the remainder of the channel, between the CB minimum point within the channel and the back surface of the channel, progressively begins contributing to the drain current, followed eventually by a rapid increase of current as the front of the channel becomes involved.

FIGS. 9C-9D show that, by thus spreading the onset of conduction, the OIP3 peak broadens even more pronouncedly, such that the width over which OIP3 is >40 dBm is about 0.12 Volts. The smooth grading scheme of this inventive device results in the drain current turning on more smoothly with increasing V_{GS}, which translates to values of gₘ₃ close to zero, and high OIP3, over a wide range of gate voltages V_{GS}.

The broadening of the OIP3 peak in these inventive devices means that the device performance is more immune to manufacturing process variations that might wash out narrower peaks. The broad peaks also mean that the HEMT remains linear under any drift in bias point caused, for example, by changing device temperature. The use of compositional grading within the channel instead of doping preserves high electron velocity vₛₐₜ.

Thus, the present invention improves the linearity characteristics of a transistor, namely the input/output intercept points (IIP3/OIP3) and intermodulation distortion (IM3), while maintaining a high transconductance (gₘ₁) and high electron velocity (vₛₐₜ) in the conducting channel. The present invention also improves the manufacturability, yield, and immunity to bias-point drift, of a linear transistor.

In one embodiment, the present invention implements a bilinear V-shaped composition grading for engineering the I_{D}-V_{GS} curve for high OIP3. In an alternative embodiment, the present invention implements a quadratic U-shaped composition grading for engineering the I_{D}-V_{GS} curve for high OIP3. In another alternative embodiment, the present invention implements triple pulse doping or even higher pulse doping for immunity to process variation as well as low parasitic leakage.

The present invention has a broader OIP3 peak with graded channels than uniform, for larger signal operation. The present invention has broader OIP3 peak with graded channels than uniform, for more room for process variation, bias-point temperature drift. The present invention has less variation of linearity with doping, hence higher yield, in triple-pulse doping over 2-pulse doping. The present invention has no leakage through barrier with 2 back pulses in a barrier, unlike a uniformly doped barrier as in the prior art. The present invention has U and V grading schemes which work even with non-polar III-Vs and even with SiGe, unlike linearly graded AlGaN as in the prior art. The present invention has high electron mobility preserved by grading, unlike heavily doped GaN spacer/uniformly doped channel as in the prior art.

In alternative embodiments, the present invention also includes piecewise linear or curved grading, such as quadratic grading or generally any arbitrary non-uniform piecewise linear or curved grading scheme, in which linearity of the operation of a FET is improved by spreading charge into spatially successive potential wells. In the alternative embodiments, the present invention includes several possible variants on the idea of composition grading for linearity, including but not limited to symmetric V-shaped and U-shaped grading profiles. For example, the present invention also includes asymmetrical V-shaped and U-shaped grading by having asymmetric piecewise curves, and grading according to any arbitrary curve, such as the hyperbolic cosine function, cos h(x). In addition, the present invention includes having more than two grades back-to-back, that is, piecewise linear and/or piecewise-quadratic grading, or combinations thereof.

Since there is an infinity of ways in which one can spatially vary the channel composition, with linear, quadratic, and hyperbolic cosine being merely three examples, the present invention includes any scheme for grading the channel that bestows linearity by spreading the channel charges spatially into one or more successive notches or wells formed by the compositional grading of the channel.

In further alternative embodiments, other types or flavors of FETs are fabricated using the linear or quadratic compositional grading as described herein. Bilinear and biquadratic compositional grading schemes are versatile and may be used to improve linearity in a large number of flavors of transistors other than HEMTs that operate based on the same physical principle, namely the field effect. These include but are not limited to: HEMT variants where the barrier semiconductor is replaced with an insulating oxide; enhancement-mode HEMTs that have a positive threshold voltage rather than the depletion-mode negative threshold devices used for illustrating the concept in this application; hole-channel FETs where the carriers of electrical current are holes rather than electrons, with grading of the valence band in which holes reside may be accomplished completely analogously to CB grading; and types or flavors of FETs that deplete a doped channel, i.e. a pre-existing bridge between the source and drain by applying a voltage opposite in polarity to the ionized impurities (dopants), which include Hetero-Junction (HFET/JFET) and Metal-Semiconductor (MESFETs), which have a good linearity to begin with, although the mobility and speed are lower than, for example, HEMTs. The grading schemes of the present invention work with doped channels as well as undoped, so the inventive grading schemes may be used to further improve the linearity figures of merit, without further impacting electron/hole mobility. This is especially true of operational bias levels where gₘ₁ is not yet constant with V_{GS}.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A field-effect transistor (FET) comprising:
a substrate;
a back barrier disposed on the substrate;
a channel disposed on the back barrier, the channel composed of an alloy and having a non-uniform gradation in an alloy composition profile; and
a front barrier disposed on the channel.

2. The FET of claim 1, wherein the channel is composed of the alloy having a plurality of constituent elements whereby a composition in the alloy of at least one of the constituent elements is alloy-compositionally graded to cause a plot of the composition as a function of depth to have a V-shape.

3. The FET of claim 1, wherein the channel is composed of the alloy having a plurality of constituent elements whereby a composition in the alloy of at least one of the constituent elements is alloy-compositionally graded to cause a plot of the composition as a function of depth to have a piecewise-linear shape, with the piecewise-linear shape having different slopes in different segments of the plot.

4. The FET of claim 1, wherein the channel is composed of the alloy having a plurality of constituent elements whereby a composition in the alloy of at least one of the constituent elements is alloy-compositionally graded to cause a plot of the composition as a function of depth to have a U-shape.

5. The FET of claim 1, wherein the channel is composed of the alloy having a plurality of constituent elements whereby a composition in the alloy of at least one of the constituent elements is alloy-compositionally graded to cause a plot of the composition as a function of depth to have a plurality of piecewise-curved shapes.

6. The FET of claim 1, wherein the channel is composed of the alloy having a plurality of constituent elements whereby a composition in the alloy of at least one of the constituent elements is alloy-compositionally graded to cause a plot of the composition as a function of depth to have a parabola shape.

7. The FET of claim 1, wherein the channel is composed of the alloy having a plurality of constituent elements whereby a composition in the alloy of at least one of the constituent elements is alloy-compositionally graded to cause a plot of the composition as a function of depth to have a hyperbolic-cosine shape.

8. (canceled)

9. The FET of claim 1, wherein the FET has a non-constant linear gₘ₁ as a function of gate voltage.

10. The FET of claim 1, wherein the substrate includes growth buffers for clean, dislocation-free growth.

11-12. (canceled)

13. The FET of claim 1, wherein at least one of the front barrier and the back barrier is composed of a semiconducting material.

14. The FET of claim 1, wherein at least one of the front barrier and the back barrier is composed of an insulating oxide.

15. The FET of claim 1, wherein the FET is an enhancement-mode device having a positive threshold voltage.

16. The FET of claim 15, wherein the FET is a high-electron mobility transistor (HEMT).

17. The FET of claim 1, wherein the FET is a depletion-mode device having a negative threshold voltage.

18. The FET of claim 1, wherein carriers of electric current in the channel are selected from electrons and electron holes.

19. The FET of claim 1, wherein the channel is doped, and the channel is depleted by applying a voltage opposite in polarity to ionized impurities in the FET.

20. The FET of claim 19, wherein the FET is selected from a hetero-junction device, a metal-semiconductor FET (MESFET), and a heterostructure FET (HFET).

21. A field-effect transistor (FET) comprising:
a substrate;
a back barrier disposed on the substrate;
a channel disposed on the back barrier, the channel composed of an alloy and having a non-uniform gradation in an alloy composition profile;
a front barrier disposed on the channel;
a first transistor terminal disposed on the front barrier;
a first conducting member and a second conducting member disposed on the front barrier with each of the first and second conducting members spaced from the first transistor terminal and spaced from each other;
a second transistor terminal disposed on the first conducting member;
a third transistor terminal disposed on the second conducting member;
a first pulse-doping layer disposed within the front barrier; and
a second pulse-doping layer disposed within the back barrier.

22. The FET of claim 21, wherein the substrate includes growth buffers for clean, dislocation-free growth.

23. A method of fabricating a field-effect transistor (FET), the method comprising:
disposing a back barrier on a substrate;
disposing a channel on the back barrier, the channel composed of an alloy and having a non-uniform gradation in an alloy composition profile; and
disposing a front barrier on the channel.
